(19) United States
(12) Patent Application Publication
(10) Pub. No.: US 2026/0052700 A1
(43) Pub. Date: Feb. 19, 2026

(54) High-Speed and High-Density Ferroelectric Memory, and Manufacturing Method Therefor and Application Thereof

(71) Applicants: BEIJING SUPERSTRING ACADEMY OF MEMORY TECHNOLOGY, Beijing (CN); PEKING UNIVERSITY, Beijing (CN)

(72) Inventors: Qianqian HUANG, Beijing (CN); Zhiyuan FU, Beijing (CN); Ru HUANG, Beijing (CN)

(21) Appl. No.: 18/996,582

(22) PCT Filed: Nov. 9, 2023
(86) PCT No.: PCT/CN2023/130630

§ 371 Date: Oct. 29, 2025

(30) Foreign Application Priority Data
Mar. 14, 2023 (CN) 202310242062.2

(51) Int. Cl. H10B 53/30

(52) U.S. Cl. CPC H10B 53/30

(57) ABSTRACT

A high-speed and high-density ferroelectric memory, and a preparation method therefor and an application thereof, belonging to the field of semiconductor memories. In the memory, multiple memory cells are arranged in an array, and the two sides of the array of the memory cells are connected to substantially orthogonal word lines and bit lines, the memory cell of the present invention adopts a stacked structure of a top electrode, a capacitance-variable dielectric layer, an intermediate metal layer, a ferroelectric dielectric layer, and a bottom electrode, which is electrically equivalent to a ferroelectric capacitor and a capacitance-variable selector connected in series, by regulating the voltage division relationship of the memory cells, the voltage division of the ferroelectric capacitor in the unselected cells is reduced, so that its disturbance is reduced; and by using the capacitors in series, the RC delay of memory cells is decreased, so as to improve the memory access speed. Therefore, the disturbance of unselected cells is reduced, the storage window of the memory is improved, the bit error rate of the memory is reduced, and the memory access speed is improved, without increasing additional area overhead.

### FIELD OF THE INVENTION

The present invention relates to the field of semiconductor memories, and in particularly to a high-speed and high-density ferroelectric memory.

### BACKGROUND OF THE INVENTION

With the continuous advancement of electronic information technology, the demand for low-power consumption and high-capacity memory is constantly increasing. Traditional flash memory (Flash) utilizes the principle of charge storage and adopts the erasing/programming method of hot electron injection and FN tunneling, which results in relatively high power consumption and relatively long erasing/programming time; while traditional dynamic random access memory (DRAM) has a relatively short memory retention time due to transistor leakage, and requires high-frequency refresh, which brings a relatively high dynamic power consumption. Nowadays, with the continuous development of intelligent Internet of Things, artificial intelligence and big data, these problems will become increasingly serious.

Ferroelectric dielectric materials, due to their asymmetric lattice structure, overall exhibit spontaneous polarization charges that can be controlled by an electric field, and the polarization reversal speed depends on the lattice relaxation time, thus memories designed based on ferroelectric materials have the advantages of low power consumption and high speed. However, traditional ferroelectric materials based on perovskite structures (such as PZT, BTO, etc.) have low compatibility with CMOS processes due to their complex composition; and the size effect is obvious, making it impossible to integrate in advanced process nodes, resulting in memories based on traditional ferroelectric materials only playing a role in some special edge applications.

In recent years, researchers have found that CMOS-compatible hafnium oxide (HfO₂) films can induce ferroelectricity under specific doping, stress and annealing conditions, breaking the constraints of difficult integration and poor miniaturization of ferroelectric material devices. Among different types of hafnium oxide-based ferroelectric memories, crossbar array memories based on ferroelectric capacitors have a relatively high storage density, can achieve a high-speed read/write of data, and have a good retention and a relatively low power consumption, and are expected to become a substitute for traditional DRAMs. However, with a further research, it has been found that HfO₂-based ferroelectric materials have the characteristics of polycrystalline and multi-domain, and the coercive field distribution of their ferroelectric domains is relatively wide, resulting in significant disturbances to unselected cells when writing and reading the selected cells in the array, which can cause serious bit-flipping problems easily. In the prior art, a resistive switching device is connected in series with the gate of a ferroelectric transistor, by utilizing the difference in resistances of the resistive switching device at different voltages, the RC delay at the gate of the unselected cells is increased to reduce the equivalent gate disturbance voltage; but this anti-interference scheme for ferroelectric transistors does not fully consider the characteristics of changes in semiconductor capacitance under different voltages, and the way of connecting the resistive switching devices in series will also increase the RC delay of selected cells and reduce the access speed of memory. Therefore, achieving high-speed and low disturbance of a crossbar array ferroelectric capacitor memory has become an urgent problem to be solved.

### SUMMARY OF THE INVENTION

The purpose of the present invention is to propose a high-speed and high-density ferroelectric memory with a lower bit error rate and a larger storage window.

The specific technical solution of the present invention is as follows:

A ferroelectric capacitor memory based on a crossbar array structure, characterized in that, in the memory, multiple memory cells are arranged in an array, and the two sides of the array of the memory cells are connected to substantially orthogonal word lines and bit lines; the memory cell is formed by stacking multiple layers of materials, which are, from top to bottom, a top electrode, a capacitance-variable dielectric layer, an intermediate metal layer, a ferroelectric dielectric layer, and a bottom electrode, a memory cell connected to both the word/bit lines can complete the read/write operation by applying positive/negative half-select voltages to the word/bit lines simultaneously.

The structure of the memory cell of the present invention adopts a top electrode, a capacitance-variable dielectric layer, an intermediate metal layer, a ferroelectric dielectric layer, and a bottom electrode, which is electrically equivalent to a ferroelectric capacitor connected in series with a capacitance-variable selector; when the voltage applied to the memory cell does not exceed a certain limit, the capacitance-variable selector is in a low capacitance state, when the voltage is high enough, metal atoms migrate and form metal filaments in the capacitance-variable dielectric layer, reducing the equivalent spacing between the electrode plates and significantly increasing the capacitance value of the capacitance-variable selector; the ferroelectric dielectric layer has a spontaneous polarization intensity that can be reversed by an external voltage, enabling non-volatile storage of data.

When positive/negative half-select voltages are applied to a pair of word/bit lines simultaneously, the memory cell connected to the word/bit lines simultaneously receives twice the half-select voltage, that is, the full-swing voltage, and this memory cell is the selected memory cell, its capacitance-variable selector changes to a high capacitance state, most of the voltage drops on the ferroelectric capacitor, causing the spontaneous polarization of the ferroelectric capacitor to reverse, that is, the selected memory cell completes the read/write operation; other memory cells connected to the corresponding word/bit lines are disturbed memory cells, which are affected by the half-select voltage, the voltage applied to the disturbed memory cell cannot change its capacitance-variable selector to a high capacitance state, thus most of the voltage of the disturbed memory cell drops on the capacitance-variable selector in the low capacitance state, thereby reducing the voltage drop of the ferroelectric capacitor in the disturbed memory cell and reducing the disturbance caused by the half-select voltage to the disturbed memory cell.

The top electrode in the above-mentioned memory cell is a material that is prone to undergo electromigration in the dielectric layer, preferably Ag; in order to provide sufficient stress during annealing to form ferroelectric crystals in the ferroelectric dielectric layer, the intermediate metal layer and bottom electrode can be selected from the following: TiN, TaN, Pt, Mo, Ru, W, etc. The capacitance-variable dielectric layer is: a dielectric material based on HfO₂ or TaOₓ and the like which can generate a capacitance-variable effect and has a metal barrier intercalation layer such as SiO₂ to avoid conduction; the ferroelectric dielectric layer: traditional ferroelectric materials such as perovskite type ferroelectrics (PZT, BFO, SBT), ferroelectric polymers (P(VDF-TrFE)) etc., or new ferroelectric materials based on HfO₂ that generate ferroelectricity under specific treatments (doping, stress, annealing, etc.) are used. In the above-mentioned ferroelectric capacitor memory based on crossbar array, the thickness of the electrode is preferably 10˜100 nm; the thickness of the capacitance-variable dielectric layer and the ferroelectric dielectric layer is preferably 8˜15 nm.

The present invention further provides an electronic device comprising the aforementioned crossbar array ferroelectric capacitor memory.

The beneficial effects of the crossbar array ferroelectric capacitor memory of the present invention:

When accessing a certain memory cell in a ferroelectric capacitor memory with a crossbar array structure, a positive/negative half-select voltage is correspondingly applied respectively to the word/bit lines where the memory cell is located, and the selected memory cell is subjected to a full swing voltage (twice the half-select voltage), so that the capacitance-variable selector of the memory cell changes to a high capacitance state, so that most of the voltage drops on the ferroelectric capacitor of the memory cell, so that ferroelectric polarization reversal occurs, and the read/write operation is completed; but the disturbed memory cell connected to the same word/bit lines is applied with the half-select voltage, so that the capacitance-variable selector of the memory cell is maintained in a low capacitance state, so that most of the voltage drops on the capacitance-variable selector of the memory cell, so that the voltage dropped on the ferroelectric capacitor is reduced, reducing the disturbance of the half-select voltage on the information stored in the ferroelectric capacitor, lowering the bit error rate of the memory, and improving the storage window. And due to the fact that the memory cell is composed of two capacitor devices connected in series, the overall capacitance value is low, so the RC delay when accessing the memory is low, which can improve the access speed of the memory. Compared with traditional crossbar array ferroelectric capacitor memories, the memory of the present invention has smaller read/write disturbances, lower bit error rates, and a larger storage window.

### BRIEF DESCRIPTION OF THE DRAWINGS

FIG. 1 is a schematic diagram of a crossbar array ferroelectric capacitor memory based on a capacitance-variable selector according to an embodiment of the present invention.

In FIG. 1:

| | |
|---|---|
| 1- Substrate | 2- Word Line, WL |
| 3-Bit Line, BL | 4- Memory Cell, Storage Cell, SC |

FIG. 2 is a schematic cross-sectional view of a single memory cell according to an embodiment of the present invention.

In FIG. 2:

5- Top Electrode, TE
6- Capacitance-variable Dielectric Layer, Upper Dielectric, UD
7- Middle Metal layer, Middle Electrode, ME
8- Ferroelectric Dielectric Layer, Lower Dielectric, LD
9- Bottom Electrode, BE

### DETAILED DESCRIPTION OF THE EMBODIMENTS

The present invention will be further explained through embodiments in conjunction with the accompanying drawings.

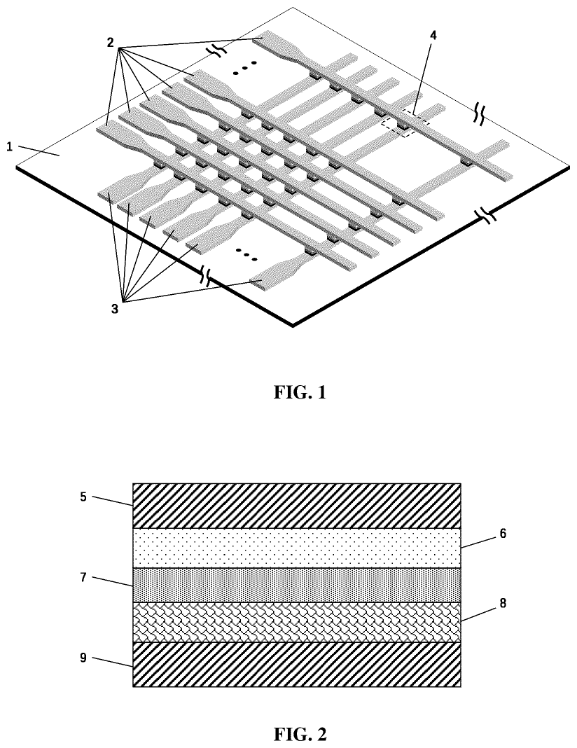

As shown in FIG. 1, this embodiment provides a crossbar array ferroelectric capacitor memory, in the memory, multiple memory cells are arranged in an array, and the two sides of the array of the memory cells are connected to substantially orthogonal word lines and bit lines. As shown in FIG. 2, wherein each memory cell is composed of a top electrode TE, a capacitance-variable dielectric layer UD, an intermediate metal layer ME, a ferroelectric dielectric layer LD, and a bottom electrode BE from top to bottom, wherein the top electrode lay is preferably Ag; the middle metal layer and the bottom electrode adopt TiN, TaN, Pt, Mo, Ru, W, etc. The capacitance-variable dielectric layer: a combination of a dielectric material based on HfO₂ or TaOₓ and the like that can generate a capacitance-variable effect and a SiO₂ metal barrier intercalation layer; the ferroelectric dielectric layer adopts traditional ferroelectric materials such as perovskite type ferroelectrics (PZT, BFO, SBT), ferroelectric polymers (P(VDF-TrFE)), or new ferroelectric materials based on HfO₂ that generate ferroelectricity under specific treatments (doping, stress, annealing, etc.). The thickness of the top electrode layer or the bottom electrode layer is preferably 10˜100 nm; the thickness of the capacitance-variable dielectric layer and the ferroelectric dielectric layer is preferably 8˜15 nm. This embodiment also provides a method for preparing the above-mentioned crossbar array ferroelectric capacitor memory, and the preparation process is as follows:
(1) preparing a bottom electrode material on a SiO₂ substrate by physical vapor deposition (PVD) method;
(2) defining a bottom electrode pattern by photolithography, and forming a bottom electrode by wet etching or dry etching methods;
(3) growing a ferroelectric dielectric material on the surface of the bottom electrode prepared in step (2) by atomic layer deposition (ALD);
(4) defining an intermediate layer metal pattern by photolithography;
(5) growing an intermediate metal material on a patterned photoresist by PVD method;
(6) stripping and shaping the intermediate layer metal by the way of removing the photoresist;
(7) continuing to grow a capacitance-variable dielectric material by ALD;
(8) defining a top electrode pattern by photolithography;
(9) growing a top electrode metal material on a patterned photoresist by PVD method;
(10) stripping and shaping a top electrode by removing the photoresist;
(11) through rapid thermal annealing (RTA) crystallization under certain conditions, the capacitance-variable dielectric material is crystallized, and the ferroelectric dielectric material generates ferroelectricity;
(12) defining a position of the bottom electrode contact hole by photolithography;
(13) etching and exposing the bottom electrode for contact.

For example, when accessing a memory cell, a positive half-select voltage V_{dd}/2 is applied correspondingly to the word line where the memory cell is located, a negative half-select voltage −V_{dd}/2 is applied to the corresponding bit line, and other word/bit lines are grounded. At this time, the selected memory cell is subjected to a full swing voltage V_{dd}, and the capacitance-variable selector in the memory cell changes to a high capacitance state, resulting in most of the voltage to drop on the ferroelectric capacitor, enabling information writing or reading of the ferroelectric capacitor; at the same time, the disturbed memory cell on the same word/bit lines is affected by the half-select voltage V_{dd}/2, and its capacitance-variable selector maintains a low capacitance state, resulting in most of the voltage to drop on the capacitance-variable selector, and the voltage division of the ferroelectric capacitor is very small, reducing the disturbance of the half-select voltage on the stored information.

The beneficial effects of the present invention are described with this embodiment:

Conventional ferroelectric crossbar array capacitor memory suffers from serious half-select disturbance voltage disturbance problems, and has the disadvantages of high bit error rate and small storage window, the memory cell of the present invention adopts a stacked structure of a top electrode, a capacitance-variable dielectric layer, an intermediate metal layer, a ferroelectric dielectric layer, and a bottom electrode to reduce the voltage division of unselected cell to reduce its disturbance; and reduce the RC delay of the cell to improve the memory access speed. In summary, the present invention improves the storage window of the memory, reduces the bit error rate and improves the access speed, without increasing additional area overhead.

Finally, it should be noted that the purpose of the disclosed embodiments is to help further understand the present invention, but those skilled in the art can understand that various substitutions and modifications are possible without departing from the spirit and scope of the present invention and the appended claims. Therefore, the present invention should not be limited to the contents disclosed in the embodiments, and the scope of protection claimed by the present invention shall be subject to the scope defined in the claims.

1. A crossbar array ferroelectric capacitor memory, characterized in that, in the memory, multiple memory cells are arranged in an array, and the two sides of the array of the memory cells are connected to substantially orthogonal word lines and bit lines, the memory cell is formed by stacking multiple layers of materials, which are, from top to bottom, a top electrode, a capacitance-variable dielectric layer, an intermediate metal layer, a ferroelectric dielectric layer, and a bottom electrode, the memory cell connected to both the word/bit lines completes the read/write operation by applying positive/negative half-select voltages to the word/bit lines simultaneously.

2. The crossbar array ferroelectric capacitor memory of claim 1, characterized in that, the capacitance-variable dielectric layer adopts a combination of a dielectric material based on HfO₂ or TaOₓ that generates a capacitance-variable effect and a SiO₂ metal barrier intercalation layer.

3. The crossbar array ferroelectric capacitor memory of claim 1, characterized in that, the ferroelectric dielectric layer adopts perovskite type ferroelectric materials, ferroelectric polymer materials, or ferroelectric materials based on HfO₂ that generate ferroelectricity after treatment.

4. The crossbar array ferroelectric capacitor memory of claim 1, characterized in that, the top electrode adopts Ag.

5. The crossbar array ferroelectric capacitor memory of claim 1, characterized in that, the intermediate metal layer and the bottom electrode adopt TiN, TaN, Pt, Mo, Ru, or W.

6. The crossbar array ferroelectric capacitor memory in claim 1, characterized in that, the thickness of the top electrode, the bottom electrode, or the intermediate metal layer is in the range of 10-100 nm.

7. The crossbar array ferroelectric capacitor memory of claim 1, characterized in that, the thickness of the capacitance-variable dielectric layer or the ferroelectric dielectric layer is in the range of 8˜15 nm.

8. A method for preparing a crossbar array ferroelectric capacitor memory, comprising the steps of:
1) preparing a bottom electrode material on a substrate by physical vapor deposition;
2) defining a bottom electrode pattern by photolithography, and forming a bottom electrode by wet etching or dry etching methods;
3) growing a ferroelectric dielectric material on the surface of the bottom electrode by atomic layer deposition;
4) defining an intermediate layer metal pattern by photolithography;
5) growing an intermediate metal layer on a patterned photoresist by physical vapor deposition method;
6) stripping and shaping the intermediate layer metal by removing the photoresist;
7) continuing to grow a capacitance-variable dielectric material by atomic layer deposition method;
8) defining a top electrode pattern by photolithography;
9) growing a top electrode metal layer on a patterned photoresist by physical vapor deposition method;
10) stripping and shaping the top electrode by removing the photoresist;
11) through rapid thermal annealing crystallization, the capacitance-variable dielectric material is crystallized, and the ferroelectric dielectric material generates ferroelectricity;
12) defining a position of contact hole of the bottom electrode by photolithography;
13) etching and exposing the bottom electrode for contact.

9. An electronic device characterized by comprising the crossbar array ferroelectric capacitor memory as described in claim 1.

10. An electronic device characterized by comprising the crossbar array ferroelectric capacitor memory as described in claim 2.

11. An electronic device characterized by comprising the crossbar array ferroelectric capacitor memory as described in claim 3.

12. An electronic device characterized by comprising the crossbar array ferroelectric capacitor memory as described in claim 4.

13. An electronic device characterized by comprising the crossbar array ferroelectric capacitor memory as described in claim 5.

14. An electronic device characterized by comprising the crossbar array ferroelectric capacitor memory as described in claim 6.

15. An electronic device characterized by comprising the crossbar array ferroelectric capacitor memory as described in claim 7.
